(19) United States
(12) Patent Application Publication
(10) Pub. No.: US 2014/0030886 A1
(43) Pub. Date: Jan. 30, 2014

(54) METHOD FOR FORMING COPPER WIRING

(71) Applicant: TOKYO ELECTRON LIMITED, Minato-ku (JP)

(72) Inventors: Takara FUKUSHIMA, Yamanashi (JP); Tadahiro Ishizaka, Yamanashi (JP); Atsushi Gomi, Yamanashi (JP); Tatsuo Hatano, Yamanashi (JP); Yasushi Mizusawa, Yamanashi (JP)

(73) Assignee: TOKYO ELECTRON LIMITED, Minato-ku (JP)

(21) Appl. No.: 14/042,198

(22) Filed: Sep. 30, 2013

Related U.S. Application Data
(63) Continuation of application No. PCT/JP2012/057919, filed on Mar. 27, 2012.

(30) Foreign Application Priority Data
Mar. 30, 2011 (JP) 2011-075147

(51) Int. Cl. H01L 21/768

(52) U.S. Cl. CPC H01L 21/76846
USPC 438/653

(57) ABSTRACT

A copper (Cu) wiring forming method includes forming a barrier film on the entire surface of a wafer which has a trench, forming a ruthenium (Ru) film on the barrier film, and filling the trench by forming a pure copper film on the ruthenium film by a physical vapor deposition (PVD). The method further includes forming a copper alloy film on the pure copper film by the PVD, forming a copper wiring by polishing the entire surface by a chemical mechanical polishing, forming a cap layer made of a dielectric material on the copper wiring, and segregating an alloy component included in the copper alloy film in a region including a portion corresponding an interface between the copper wiring and the cap layer.

This application is a Continuation Application of PCT International Application No. PCT/JP2012/057919 filed on Mar. 27, 2012, which designated the United States.

### FIELD OF THE INVENTION

The present invention relates to a copper (Cu) wiring forming method for forming a copper wiring in a recess such as a trench or a hole formed on a substrate.

### BACKGROUND OF THE INVENTION

In general, various processes such as film formation, etching and the like are repeatedly performed on a semiconductor wafer to manufacture a desired semiconductor device. Recently, in order to meet demands for high-speed semiconductor device, miniaturization of a wiring pattern and high level of integration, it is required to realize low resistance of wiring (high conductivity) and high electromigration resistance.

Accordingly, Copper (Cu) having a high electromigration resistance and a higher conductivity (lower resistance) has been investigated as an alternative wiring material to Al or W.

As for the Cu wiring forming method, there has been proposed a technique including: forming a barrier film formed of Ta, Ti, TaN, TiN or the like on an entire interlayer insulating film having a trench and/or a hole by a plasma sputtering as an example of a physical vapor deposition (PVD); forming a Cu seed film on the barrier film by the plasma sputtering; filling a trench and/or a hole by performing a Cu plating; and removing a residual Cu thin film or a residual barrier film remaining on the wafer surface by a chemical mechanical polishing (CMP) (see, e.g., Patent Document 1). Further, a cap layer made of a dielectric material such as SiCN, SiN or the like is formed on the wiring layer (Cu film) after the CMP processing.

In addition, there is proposed a technique for forming wiring by using a Cu alloy such as Cu—Al, Cu—Mn, Cu—Mg, Cu—Ag, Cu—Sn, Cu—Pb, Cu—Zn, Cu—Pt, Cu—Au, CuNi, Cu—Co or the like as a seed layer, instead of a Cu seed layer, in order to improve reliability of the Cu wiring (see, e.g., Non-Patent Document 1).
Patent Document 1: Japanese Patent Application Publication No. 2006-148075
Non-Patent Document 1: Nogami et. al. IEDM2010 pp 764-767

However, when the cap layer made of a dielectric material such as SiCN, SiN or the like is formed on the wiring layer (Cu film) after the CMP processing, the adhesivity between the cap layer and Cu is not sufficiently strong, which results in a void in the interface therebetween. This indicates that the reliability is insufficient. Moreover, in the technique described in Non-Patent Document 1, a metal (Co, CoWP, CVD-Ru or the like) is used for the cap layer, so that the problem of poor adhesion between the cap layer and Cu does not occur. However, this leads to an increase in a wiring resistance because an alloy component in the cap layer is contained in the wiring in addition to impurities from the Cu plating.

### SUMMARY OF THE INVENTION

In view of the above, the present invention provides a method for forming a Cu wiring having a low wiring resistance and good adhesivity to a cap layer when forming the Cu wiring by filling Cu in a recess such as a trench or a hole.

In accordance with a first aspect of the present invention, there is provided a Cu wiring forming method for forming a Cu wiring by filling Cu in a recess, which is formed in a substrate in a predetermined pattern, the Cu wiring forming method including: forming a barrier film at least on a surface of the recess; forming a pure Cu film by a physical vapor deposition (PVD) so that pure Cu exists at least on a surface in the recess; forming a Cu alloy film formed of a Cu alloy beyond an upper end of the recess by the PVD; forming a Cu wiring in the recess by polishing the entire surface of the substrate by a chemical mechanical polishing; forming a cap layer made of a dielectric material on the Cu wiring; and forming a segregation layer of an alloy component contained in the Cu alloy film by segregating the alloy component in a region including a portion corresponding to an interface between the Cu wiring and the cap layer by diffusing the alloy component in the Cu alloy film before the forming the cap layer and/or during the forming the cap layer. Further, the segregation layer of the alloy component is formed in the interface between the Cu wiring and the cap layer.

The Cu wiring forming method described above may further include forming a Ru film between the forming the barrier film and the forming the pure Cu film. Further, the Ru film may be formed by a chemical vapor deposition.

Further, in the forming the pure Cu film, the pure Cu may be entirely filled in the recess, a pure Cu seed film may be formed as the pure Cu film on the surface in the recess, or the pure Cu may be filled such that an upper space in the recess remains empty.

Further, the forming the segregation layer of the alloy component may include annealing the substrate after the forming the Cu alloy film, heating the substrate during the forming the Cu alloy film, heating the substrate during the forming the cap layer, or the combination thereof.

Further, the forming the pure Cu film may be carried out by an apparatus for generating a plasma with a plasma generation gas in a processing chamber where the substrate is accommodated, ionizing Cu scattered from a target formed of the pure Cu in the plasma, and attracting Cu ions onto the substrate by applying a bias power to the substrate. Further, the forming the Cu alloy film may also be carried out by the apparatus except that a target is formed of the Cu alloy.

Further, the Cu alloy forming the Cu alloy film may be selected from a group consisting of Cu—Al, Cu—Mn, Cu—Mg, Cu—Ag, Cu—Sn, Cu—Pb, Cu—Zn, Cu—Pt, Cu—Au, CuNi, Cu—Co, and Cu—Ti. Further, it is preferable to select Cu—Mn and Cu—Al, and it is more preferable to select Cu—Mn.

Further, the barrier film may be selected from a group consisting of a Ti film, a TiN film, a Ta film, a TaN film, a Ta/TaN bilayered film, a TaCN film, a W film, a WN film, a WCN film, a Zr film, a ZrN film, a V film, a VN film, a Nb film and a NbN film. Further, the barrier film may be formed by the PVD.

In accordance with a second aspect of the present invention, there is provided a storage medium storing a program executed on a computer to control a Cu wiring forming system, wherein the program, when executed on the computer, controls the Cu wiring forming system to perform the Cu wiring forming method, which includes: forming a barrier film at least on a surface of the recess; forming a pure Cu film by a physical vapor deposition (PVD) so that pure Cu exists at least on a surface in the recess; forming a Cu alloy film formed of a Cu alloy beyond an upper end of the recess by the PVD; forming a Cu wiring in the recess by polishing the entire surface of the substrate by a chemical mechanical polishing; forming a cap layer made of a dielectric material on the Cu wiring; and forming a segregation layer of an alloy component contained in the Cu alloy film by segregating the alloy component in a region including a portion corresponding to an interface between the Cu wiring and the cap layer by diffusing the alloy component in the Cu alloy film before the forming the cap layer and/or during the forming the cap layer, wherein the segregation layer of the alloy component is formed in the interface between the Cu wiring and the cap layer.

### BRIEF DESCRIPTION OF THE DRAWINGS

FIG. 1 is a flowchart showing a Cu wiring forming method in accordance with a first embodiment of the present invention.

FIGS. 2A to 2H are process cross sectional views for explaining the Cu wiring forming method in accordance with the first embodiment of the present invention.

FIG. 3 is a flowchart showing a Cu wiring forming method in accordance with a second embodiment of the present invention.

FIGS. 4A to 4H are process cross sectional views for explaining the Cu wiring forming method in accordance with the second embodiment of the present invention.

FIG. 5 is a flowchart showing a Cu wiring forming method in accordance with a third embodiment of the present invention.

FIGS. 6A to 6H are process cross sectional views for explaining the Cu wiring forming method in accordance with the third embodiment of the present invention.

FIG. 7 is a SIMS chart showing a measurement result of distributions for respective elements in a depth direction in the case of annealing a sample having a Cu—Al film.

FIG. 8 shows a sample structure for examining a Mn diffusion from a Cu—Mn film into a Cu film.

FIG. 9 is a SIMS chart showing a measurement result of a Mn distribution in a depth direction in the case of performing and not performing annealing on the sample shown in FIG. 8.

FIG. 10 is a top view showing an example of a multi chamber type film forming system suitable for implementation of the Cu wiring forming methods in accordance with the first to the third embodiments of the present invention.

FIG. 11 is a cross sectional view showing a Cu wiring forming apparatus for forming a pure Cu film, which is installed in the film forming system shown in FIG. 10.

FIG. 12 is a cross sectional view showing a Ru film forming apparatus installed in the film forming system shown in FIG. 10.

### DETAILED DESCRIPTION OF THE EMBODIMENTS

Hereinafter, embodiments of the present invention will be described in detail with reference to the accompanying drawings.

<First Embodiment of Cu Wiring Forming Method>

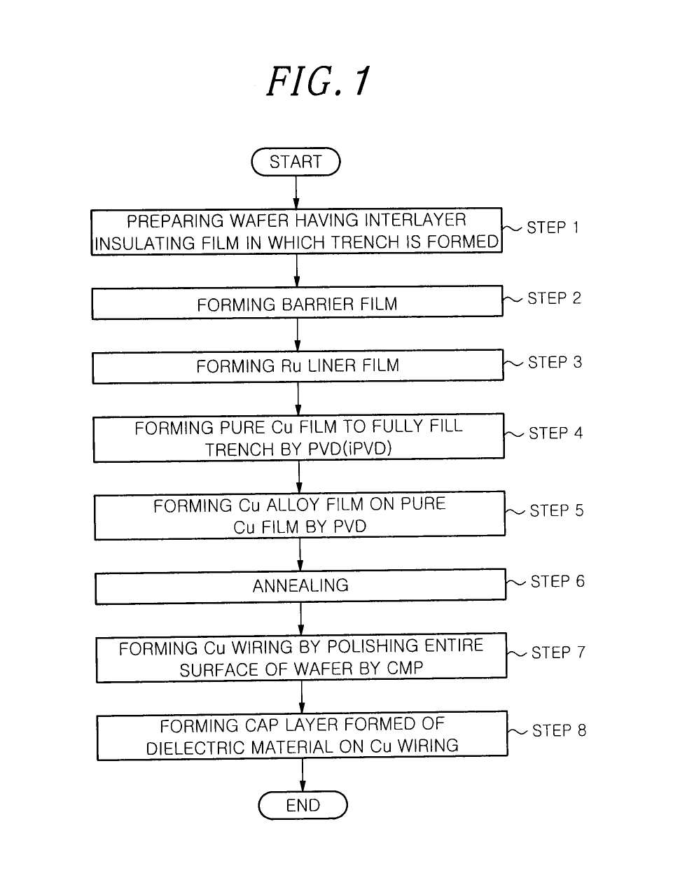

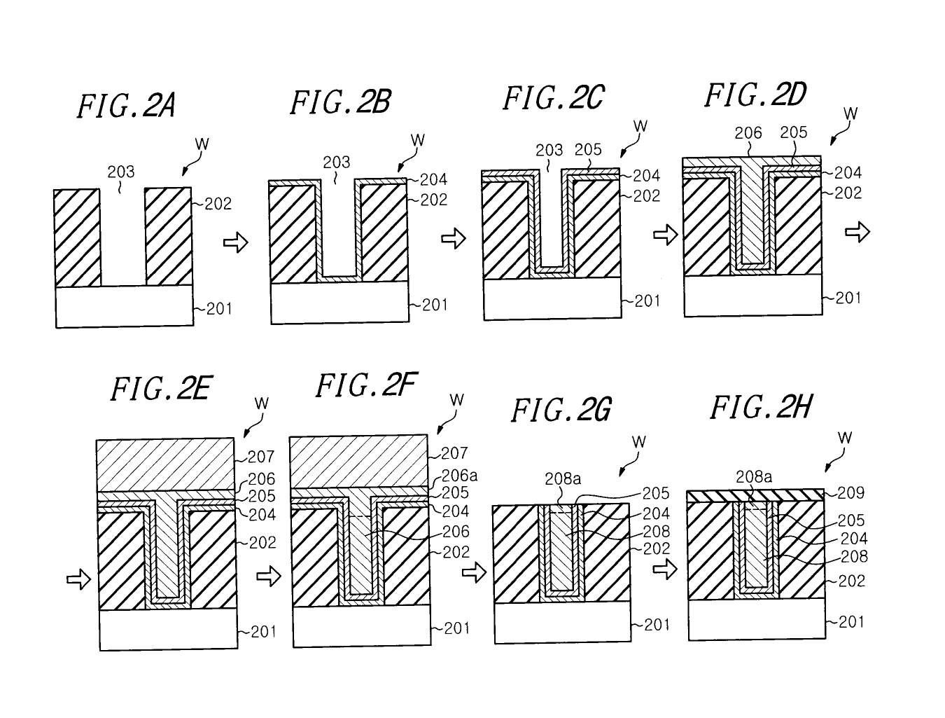

A Cu wiring forming method in accordance with a first embodiment of the present invention will be described with reference to a flowchart shown in FIG. 1 and a process cross sectional view shown in FIGS. 2A to 2H.

In the present embodiment, first, there is prepared a semiconductor wafer (hereinafter, simply referred to as “wafer”) W including: a base structure 201 (detailed description is omitted); an interlayer insulating film 202 such as a SiO₂ film, a Low-k film (SiCO, SiCOH or the like) or the like formed on the base structure 201; and a trench 203 and a via (not shown) for connection with a lower wiring, formed in a predetermined pattern (step 1, FIG. 2A) as a recess. As for the wafer W, it is preferable to remove etching/ashing residue or moisture from a surface of an insulating film by a Degas process or a Pre-Clean process.

Next, a barrier film 204 for suppressing diffusion of Cu by shielding Cu (acting as a barrier against Cu) is formed on the entire surface including the surfaces of the via and the trench 203 (step 2, FIG. 2B).

As for the barrier film 204, it is preferable to use a film having a high barrier property and a low resistance, e.g., a Ti film, a TiN film, a Ta film, a TaN film, or a Ta/TaN bilayered film. It is also possible to use a TaCN film, a W film, a WN film, a WCN film, a Zr film, a ZrN film, a V film, a VN film, an Nb film, an NbN film or the like. The resistance of the Cu wiring gets lower as the volume of Cu filled in the recess is increased. Therefore, the barrier film preferably has a considerably thin thickness in a range from about 1 nm to 20 nm, and more preferably in a range from about 1 nm to 10 nm. The barrier film can be formed by an ionized physical vapor deposition (iPVD), e.g., a plasma sputtering. It can also be formed by another physical vapor deposition (PVD) such as a conventional sputtering, an ion plating or the like, a chemical vapor deposition (CVD), an atomic layer deposition (ALD), or a plasma CVD or a plasma ALD.

Next, a Ru liner film 205 is formed on the barrier film 204 (step 3, FIG. 2C). In order to realize a low resistance of wiring by increasing the filling volume of Cu, the Ru liner film preferably has a thin thickness in a range from about 1 nm to 5 nm.

Since Ru has high wettability to Cu, forming the Ru liner film at the base of Cu ensures good mobility of Cu in forming a Cu film by the iPVD, and it can suppress to form an overhang which blocks an opening of the trench or the hole. Therefore, Cu can be reliably filled even in a fine trench or hole without forming a void therein.

The Ru liner film is preferably formed by a thermal CVD while using Ru₃(CO)₁₂ as a film forming material. Accordingly, a thin Ru film having high purity can be formed with a high step coverage. The film forming conditions are as follows: a pressure in the processing chamber ranging from about 1.3 Pa to 66.5 Pa; and a film forming temperature (wafer temperature) ranging from about 150° C. to 250° C. The Ru liner film 205 may be formed by the PVD or the CVD using another film forming material other than Ru₃(CO)₁₂, such as a ruthenium pentadienyl compound, e.g., (cyclopentadienyl)(2,4-dimethylpentadienyl)ruthenium, bis(cyclopentadienyl)(2,4-methylpentadienyl)ruthenium, (2,4-dimethylpentadienyl)(ethylcyclopentadienyl)ruthenium, or bis(2,4-methylpentaenyl)(ethylcyclopentadienyl)ruthenium.

Further, when the opening of the trench or the via is wide and the overhang is hardly formed, it is not necessary to form the Ru liner film 205, and the Cu film may be directly formed on the barrier film.

Next, a pure Cu film 206 is formed by the PVD to almost fully fill the trench 203 and the via (not shown) (step 4, FIG. 2D). The film formation at this time is preferably performed by the iPVD, e.g., the plasma sputtering.

In the conventional PVD film formation, the overhang that blocks (covers) the opening of the trench or the hole is easily formed due to agglomeration of Cu. However, when the iPVD is used to control the film formation by Cu ions and the etching by ions (Ar ions) of the plasma generation gas and adjust the bias power applied to the wafer, the formation of the overhang can be suppressed due to the mobile Cu. Accordingly, good fillability can be obtained even in a trench or a hole having a narrow opening. At this time, it is preferable to perform a high-temperature process (in a temperature ranging from about 65° C. to 350° C.) in which Cu is migrated in order to ensure mobility of Cu and obtain good fillability. Further, as described above, by providing the Ru liner film 205 having high wettability to Cu at the base of the Cu film, Cu moves without agglomeration on the Ru liner film. Accordingly, the formation of overhang can be suppressed even in the fine recess, and Cu can be reliably filled therein without forming a void.

When the overhang is hardly formed due to a large opening width of a trench or a hole, the film formation can be performed at a high speed by a low-temperature process (in a temperature ranging from −50° C. to 0° C.) in which the migration of Cu does not occur.

After the pure Cu is filled in the trench 203 and the via (hole), a Cu alloy film 207 is formed on the pure Cu film 206 by the PVD (step 5, FIG. 2E). This process is performed to form a segregation layer in which an alloy component is segregated in an interface between a cap layer to be formed later and the Cu wiring.

Cu alloy may be Cu—Al, Cu—Mn, Cu—Mg, Cu—Ag, Cu—Sn, Cu—Pb, Cu—Zn, Cu—Pt, Cu—Au, CuNi, Cu—Co, Cu—Ti or the like. Herein, Cu—Mn, Cu—Al is preferably used and Cu—Mn is more preferably used.

The Cu alloy film 207 also functions as a lamination layer that is laminated beyond an upper end of the trench for a flattening process to be performed later by a chemical mechanical polishing (CMP). The Cu alloy film 207 is formed after the trench or the via (hole) is filled with the pure Cu film 206, so that there is no need to consider the fillability. Further, although the Cu alloy film 207 may be formed by the iPVD, it can also be formed by any PVD methods as long as the PVD method is used.

Upon completion of forming the Cu alloy film 207, an annealing process is performed when necessary (step 6, FIG. 2F). This annealing process is performed, so that the alloy component is diffused and the alloy component (Al, Mn or the like) of the Cu alloy film 207 is segregated in a region including a portion corresponding to the interface between a cap layer to be formed later and a Cu wiring. Accordingly, a segregation layer 206a is formed at an upper portion of the pure Cu film 206. However, the annealing process is not necessary when the wafer W is heated sufficiently high enough during the film formation of the Cu alloy film 207 such that the alloy component can be segregated at the portion corresponding to the interface between the Cu wiring and the cap layer to be formed after the diffusion of the alloy component.

Next, the entire surface of the wafer W is polished by the CMP, and is flattened by removing the Cu alloy film 207, the Ru liner film 205 and the barrier film 204 which are laminated (step 7, FIG. 2G). Accordingly, the Cu wiring 208 is formed in the trench and the via (hole).

Thereafter, a cap layer 209 made of a dielectric material, e.g., SiCN, is formed on the Cu wiring 208 that has been subjected to the CMP polishing (step 8, FIG. 2H). The film formation at this time may be performed by the CVD.

Before the cap layer 209 is formed, a segregation layer 208a (corresponding to the segregation layer 206a) in which an alloy component is segregated is present on the surface portion of the Cu wiring 208, as shown in FIG. 2G. In this state, the cap layer 209 is formed as shown in FIG. 2H, so that the segregation layer 208a in which an alloy component is segregated is present in the interface between the cap layer 209 and the Cu wiring 208.

Therefore, a sufficient amount of the alloy component is present in the interface between the cap layer 209 and the Cu wiring 208 to thereby improve the adhesivity between the cap layer 209 and the Cu wiring 208. In other words, the alloy component, e.g., Mn, is easily bonded with oxygen and Cu, so that the bonding with oxygen provided through the cap layer 209 results in an improvement in the adhesivity. Further, since the alloy component is segregated in the interface between the cap layer 209 and the Cu wiring 208, the concentration of the alloy component existing in the Cu wiring 208 is low and the resistance is decreased compared to the case where a wiring is made of a Cu alloy. Moreover, since the Cu wiring 208 is formed by filling Cu through the PVD, the amount of impurities is substantially small and the grain size is large compared to the case where Cu is filled by plating. Accordingly, even though a small amount of the alloy component is present, there can be obtained the Cu wiring having a resistance lower than that of the Cu wiring formed by the conventional Cu plating.

When the wafer W is heated to a temperature sufficiently high enough for the alloy component to be diffused during the film formation of the cap layer 209, the segregation of the alloy component at the portion corresponding to the interface between the cap layer 209 and the Cu wiring 208 can be further enhanced by the heat thus generated. In that case, the segregation of the alloy component can be achieved during both the formation and/or annealing of the Cu alloy film and the formation of the cap layer. Meanwhile, when the film formation temperature of the cap layer 209 is high enough, the segregation of the alloy component at the portion corresponding to the interface between the cap layer 209 and the Cu wiring 208 may be made only during the formation of the cap layer 209.

Among the above series of processes, the step 2 of forming the barrier film 204, the step 3 of forming the Ru liner film 205, the step 4 of forming the Cu film, and the step 5 of forming the Cu alloy film 207 are preferably performed consecutively in vacuum without being exposed to the atmosphere. However, the exposure to the atmosphere may occur between the above steps.

<Second Embodiment of the Cu Wiring Forming Method>

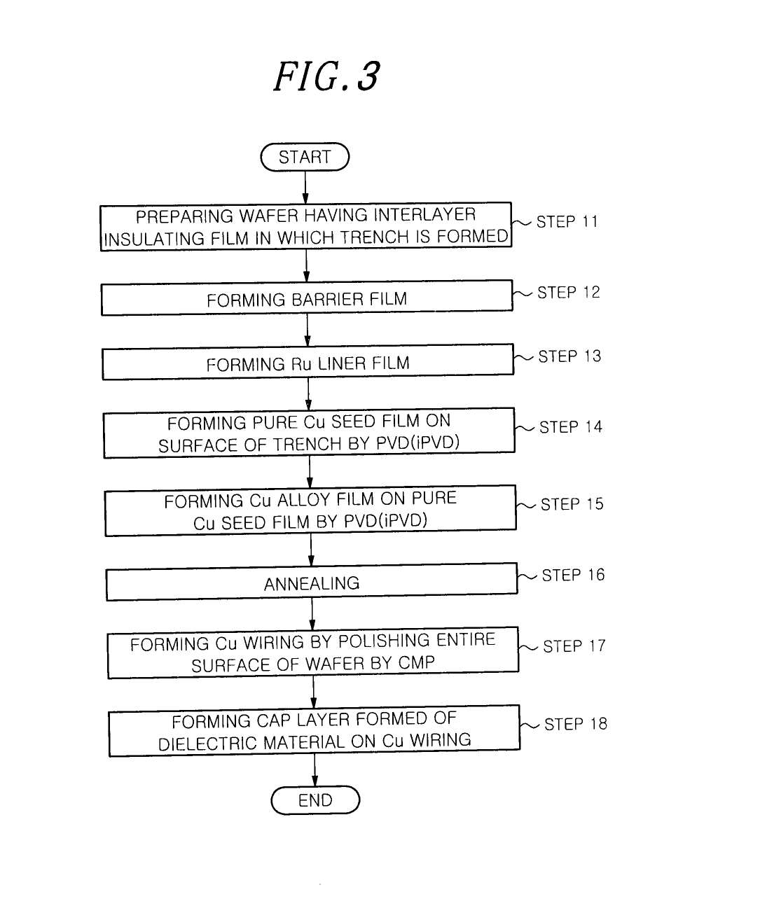

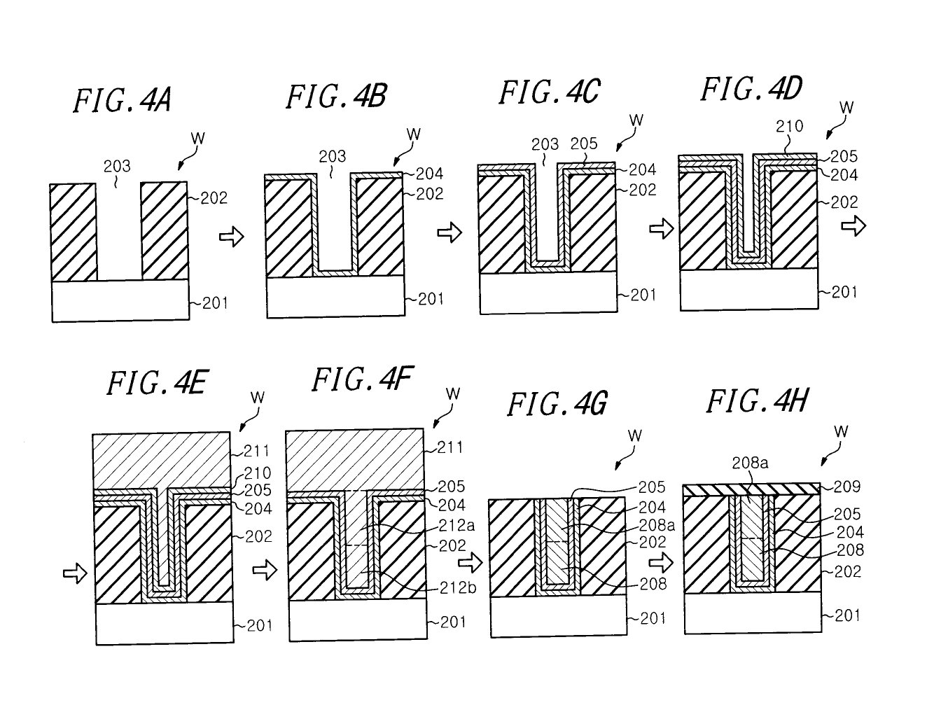

Hereinafter, a Cu wiring forming method in accordance with a second embodiment of the present invention will be described with reference to a flowchart shown in FIG. 3 and a process cross sectional view shown in FIGS. 4A to 4H.

As described in the first embodiment, in the present embodiment, there is provided a wafer W including: a base structure 201 (detailed description is omitted); an interlayer insulating film 202 such as a SiO₂ film, a Low-k film (SiCO or SiCOH) or the like formed on the base structure 201; and a trench 203 and a via (not shown) for connection with a lower wiring, formed in a predetermined pattern (step 11, FIG. 4A) as a recess.

Next, in a same manner as described in the first embodiment, a barrier film 204 for blocking Cu diffusion is formed on the entire surface including the surfaces of the via and the trench 203 (step 12, FIG. 4B). Then, a Ru liner film 205 is formed on the barrier film 204 (step 13, FIG. 4C).

Thereafter, a pure Cu seed film 210 formed of pure Cu is formed on the surfaces of the via (not shown) and the trench 203 by plasma sputtering as an example of the iPVD (step 14, FIG. 4D).

After the pure Cu seed film 210 is formed in the trench 203 and the via (hole), a Cu alloy film 211 is formed thereon by the PVD (step 15, FIG. 4E). This process is performed in order to form a segregation layer by segregating an alloy component in the interface between the Cu wiring and the cap layer to be formed later. As for the Cu alloy, one of those described in the first embodiment may be used.

The Cu alloy film 211 also serves as a lamination layer that is laminated beyond the upper end of the trench for a flattening process to be performed later by the CMP. The Cu alloy film 211 may be formed by any PVD methods. However, since the Cu alloy film 211 is filled in the trench or the via (hole) unlike the Cu alloy film 207 of the first embodiment, it is preferable to form the Cu alloy film 211 by a method capable of ensuring good fillability. Therefore, the iPVD is preferably used to form the Cu alloy film 211.

Upon completion of forming the Cu alloy film 211, an annealing is performed when necessary (step 16, FIG. 4F). By performing the annealing process, the alloy component (Al, Mn or the like) of the Cu alloy film 211 is diffused, and there are formed in the trench or the via (hole) a high-concentration region 212a, which contains a large amount of the alloy component in a region including a portion corresponding to the interface between the Cu wiring and the cap layer to be formed later, and a low concentration region 212b, containing a comparatively small amount of the alloy component, formed below the high-concentration region 212a. However, the annealing is unnecessary when the wafer W is heated sufficiently high enough during the formation of the Cu alloy film 211 such that the alloy component can be segregated in the portion corresponding to the interface between the Cu wiring and the cap layer to be formed later.

Next, the entire surface of the wafer W is polished by the CMP and is flattened by removing the Cu alloy film 211, the Ru liner film 205, and the barrier film 204 (step 17, FIG. 4G). Accordingly, the Cu wiring 208 is formed in the trench 203 and the via (hole).

Thereafter, as described in the first embodiment, the cap layer 209 made of a dielectric material, e.g., SiCN, is formed on the Cu wiring 208 (step 18, FIG. 4H).

In the present embodiment as well, before the cap layer 209 is formed, the segregation layer 208a (corresponding to the high-concentration region 212a) in which the alloy component is segregated is present at the surface of the Cu wiring 208, as shown in FIG. 4G. In this state, the cap layer 209 is formed as shown in FIG. 4H, so that the segregation layer 208a in which the alloy component is segregated is present in the interface between the cap layer 209 and the Cu wiring 208.

Accordingly, a sufficient amount of the alloy component is present in the interface between the cap layer 209 and the Cu wiring 208 to thereby improve the adhesivity between the cap layer 209 and the Cu wiring 208. In other words, the alloy component, e.g., Mn, is easily bonded with oxygen and Cu, so that the bonding with oxygen provided through the cap layer 209 results in an improvement in the adhesivity. Further, since the alloy component is segregated in the interface between the cap layer 209 and the Cu wiring 208, the concentration of the alloy component existing in the Cu wiring 208 is low, and the resistance is decreased compared to the case where a wiring is formed of a Cu alloy. Moreover, since the Cu wiring 208 is formed by filling Cu through the PVD, the amount of impurities is substantially small and the grain size is large compared to the case where Cu is filled by the plating. Therefore, even though the alloy component slightly exists, there can be obtained a Cu wiring having a lower resistance than that of the Cu wiring formed by the conventional Cu plating.

In the present embodiment, when the wafer W is heated to a temperature sufficiently high enough for the alloy component to be diffused during the film formation of the cap layer 209, the segregation of the alloy component in the portion corresponding to the interface between the cap layer 209 and the Cu wiring 208 can be enhanced by the heat thus generated. In that case, the segregation of the alloy component can be achieved during both the formation and/or annealing of the Cu alloy film and the formation of the cap layer. Meanwhile, when the film formation temperature of the cap layer 209 is high enough, the segregation of the alloy component in the portion corresponding to the interface between the cap layer 209 and the Cu wiring 208 may be made only during the formation of the cap layer 209.

In the present embodiment, the Cu alloy film 211 is formed after the pure Cu seed film 210 is formed instead of the pure Cu film 206 that fills the trench in the first embodiment, so that the amount of alloy component is increased compared to that of the first embodiment. Therefore, it is effectively used in the case of segregating a larger amount of the alloy component in the SiCN—Cu interface.

<Third Embodiment of the Cu Wiring Forming Method>

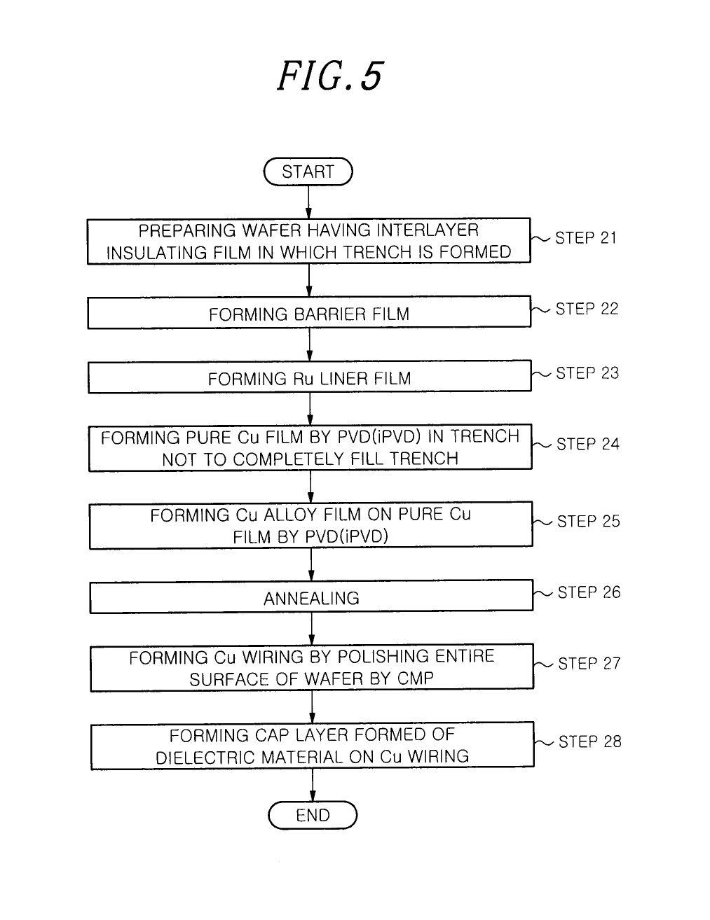

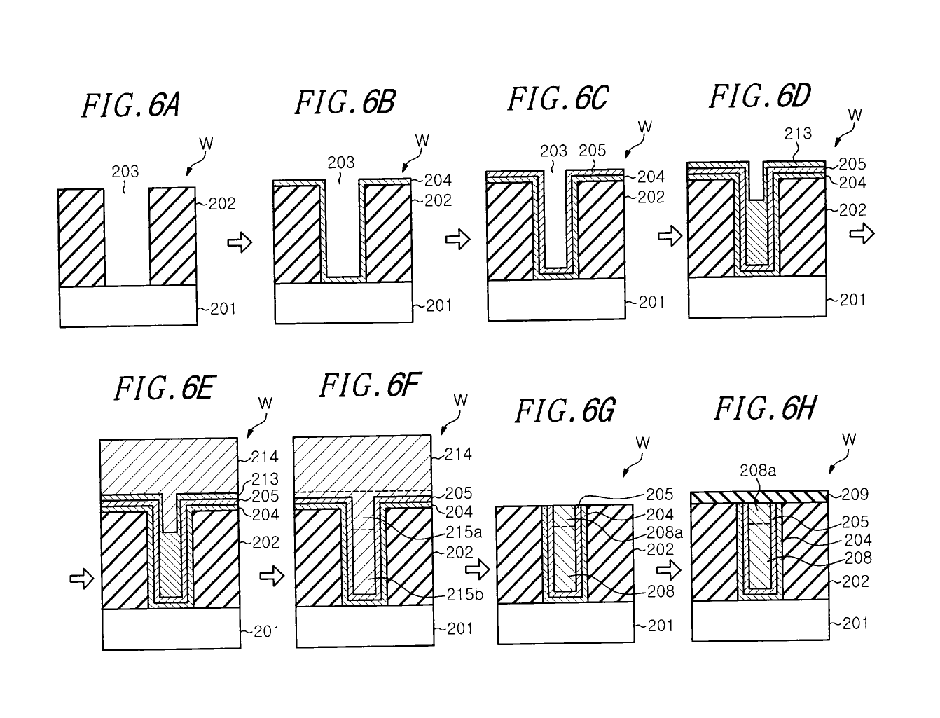

Hereinafter, a Cu wiring forming method in accordance with a third embodiment of the present invention will be described with reference to the flowchart shown in FIG. 5 and the process cross sectional views shown in FIGS. 6A to 6H.

As described in the first and the second embodiment, in the present embodiment, there is prepared a wafer W including: a base structure 201 (detailed description is omitted); an interlayer insulating film 202 such as a SiO₂ film, a Low-k film (SiCO, SiCOH or the like) or the like formed on the base structure 201; and a trench 203 and a via (not shown) for connection with a lower wiring, formed in a predetermined pattern (step 21, FIG. 6A) as a recess.

Next, in a same manner as described in the first and the second embodiment, a barrier film 204 blocking Cu diffusion is formed on the entire surface including the surfaces of the via and the trench 203 (step 22, FIG. 6B). Then, a Ru liner film 205 is formed on the barrier film 204 (step 23, FIG. 6C).

Next, a pure Cu film 213 is formed by plasma sputtering as an example of the iPVD in the trench 203 and the via (not shown) not to completely fill the trench 203 and the via (that is, the upper spaces in the trench 203 and the via remain empty) (step 24, FIG. 6D).

After the pure Cu film 213 is formed in the trench 203 and the via (hole), a Cu alloy film 214 is formed thereon by the PVD (step 25, FIG. 6E). This process is performed to form a segregation layer by segregating an alloy component in the interface between the cap layer to be formed later and the Cu wiring. As for the Cu alloy, one of those described in the first embodiment may be used.

The Cu alloy film 214 also serves as a lamination layer that is laminated beyond the upper end of the trench for a flattening process to be performed later by the CMP. The Cu alloy film 214 may be formed by any PVD methods. However, since the Cu alloy film 214 is filled in the trench or the via (hole), it is preferable to form the Cu alloy film 214 by a method capable of ensuring good fillability, as in the case of forming the Cu alloy film 211 of the second embodiment. Therefore, the iPVD is preferably used to form the Cu alloy film 214.

Upon completion of forming the Cu alloy film 214, an annealing is performed when necessary (step 26, FIG. 6F). By performing the annealing process, the alloy components (Al, Mn or the like) of the Cu alloy film 214 are diffused, and there are formed in the trench or the via (hole) a high-concentration region 215a, which contains a large amount of the alloy component in a region including a portion corresponding to the interface between the Cu wiring and the cap layer to be formed later, and a low concentration region 215b, containing a comparatively small amount of the alloy component, formed below the high-concentration region 215a. However, the annealing is unnecessary when the wafer W is heated sufficiently high enough during the formation of the Cu alloy film 214 such that the alloy component can be segregated in the portion corresponding to the interface between the Cu wiring and the cap layer to be formed later.

Next, the entire surface of the wafer W is polished by the CMP and is flattened by removing the Cu alloy film 214, the Ru liner film 205, and the barrier film 204 (step 27, FIG. 6G). Accordingly, the Cu wiring 208 is formed in the trench 203 and the via (hole).

Thereafter, as described in the first and the second embodiment, a cap layer 209 made of a dielectric member, e.g., SiCN, is formed on the Cu wiring 208 (step 28, FIG. 6H).

In the present embodiment as well, before the cap layer 209 is formed, the segregation layer 208a (corresponding to the high concentration region 215a) in which the alloy component is segregated is present on the surface of the Cu wiring 208 as shown in FIG. 6G. In this state, the cap layer 209 is formed as shown in FIG. 6H, so that the segregation layer 208a in which the alloy component is segregated is thus present in the interface between the cap layer 209 and the Cu wiring 208.

Accordingly, a sufficient amount of the alloy component is present in the interface between the cap layer 209 and the Cu wiring 208 to thereby improve the adhesivity between the cap layer 209 and the Cu wiring 208. In other words, the alloy component, e.g., Mn, is easily bonded with oxygen and Cu, so that the bonding with oxygen provided through the cap layer 209 results in an improvement in the adhesivity. Further, since the alloy component is segregated in the interface between the cap layer 209 and the Cu wiring 208, the concentration of the alloy component existing in the Cu wiring 208 is low, and the resistance is decreased compared to the case where a wiring is formed of a Cu alloy. Moreover, since the Cu wiring 208 is formed by filling Cu through the PVD, the amount of impurities is substantially small and the grain size is large compared to the case where Cu is filled by plating. Thus, even though a small amount of alloy components exists, there can be obtained a Cu wiring having a resistance lower than that of the Cu wiring formed by the conventional Cu plating.

In the present embodiment as well, when the wafer W is heated to a temperature sufficiently high enough for the alloy component to be diffused during the formation of the cap layer 209, the segregation of the alloy components in the portion corresponding to the interface between the cap layer 209 and the Cu wiring 208 can be further enhanced by the heat thus generated. In that case, the segregation of the alloy component can be achieved during both the formation and/or annealing of the Cu alloy film and the formation of the cap layer. Meanwhile, when the film formation temperature of the cap layer 209 is high enough, the segregation of the alloy component in the portion corresponding to the interface between the cap layer 209 and the Cu wiring 208 may be made only during the formation of the cap layer 209.

In the first embodiment, the alloy component may not sufficiently be concentrated in a region corresponding to the interface between the cap layer and the Cu wiring, because the interface segregated by annealing or the like is polished during the CMP. In that case, the alloy component may be re-segregated during the formation of the cap layer 209. However, when a sufficient amount of heat is not applied during the formation of the cap layer 209, the amount of the alloy component in the interface may be insufficient. Therefore, in the present embodiment, the pure Cu film 213 is formed such that the trench is not completely filled with pure Cu to remain the upper space therein empty and, then, the Cu alloy film 214 is formed. Accordingly, a segregation layer having a high concentration of the alloy component can remain even after the completion of the CMP. As a result, even when the cap layer 209 is formed at a low temperature, the adhesivity between the cap layer 209 and the Cu wiring 208 can be improved.

<Test for Examining Diffusion of Alloy Components in Cu>

Hereinafter, a test for examining diffusion of alloy components in Cu will be described.

(1) In the Case of Using Al as an Alloy Component

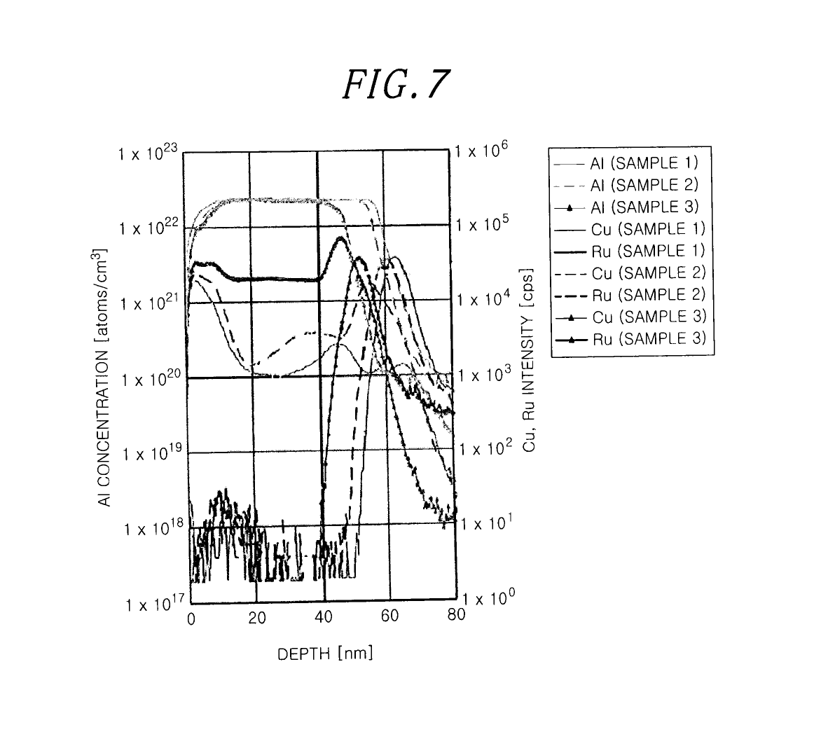

Here, in order to examine diffusion of Al serving as an alloy component, a TiN barrier film of 4 nm and a Ru film of 3 nm were formed. Then, in Sample 1, a pure Cu film of 35 nm and a Cu—Al film of 15 nm were formed in that order. In Sample 2, a pure Cu film of 25 nm and a Cu—Al film of 25 nm were formed in that order. In Sample 3, only a Cu—Al film of 50 nm was formed. All of Samples 1 to 3 were subjected to annealing at a temperature of 400° C. for 30 min. FIG. 7 shows a result of distributions of the respective elements in a depth direction which were measured by the secondary ion mass spectrometry (SIMS).

As shown in FIG. 7, all of Samples 1 to 3 could have a state in which Al was segregated at a surface side by the diffusion of the alloy component of Al. From this, it is clear that the alloy component of Al can be segregated in the interface between the cap layer and the Cu wiring in the above-described three embodiments.

Further, since Al serving as the alloy component is easily bonded with oxygen and Cu, the adhesivity between the cap layer and the Cu—Al alloy film can be improved.

(2) In the Case of Using Mn as an Alloy Component

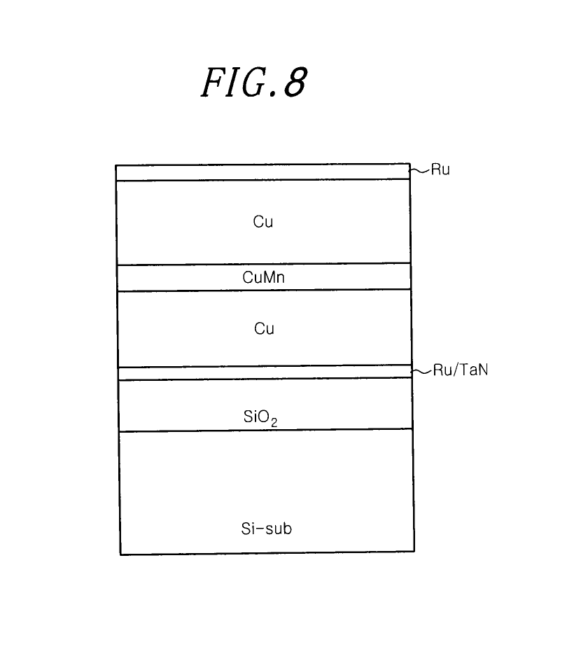

Here, in order to examine diffusion of Mn serving as an alloy component, a blanket sample was obtained by forming a TiN barrier film of 4 nm by the iPVD, a Ru film of 3 nm by the CVD, a pure Cu film of 100 nm by the iPVD, a CuMn film (Mn: 2 at %) of 20 nm by the iPVD, a pure Cu film of 100 nm by the iPVD, and a Ru film of 3 nm by the CVD in that order on a wafer in which a thermal oxide (SiO₂) film was formed on a Si substrate as shown in FIG. 8. By sandwiching the CuMn film with the pure Cu films, it was possible to observe the effect of Mn diffusion only.

With respect to the blanket sample, the Mn concentration in a depth direction was observed by the SIMS in each of the case when the sample was annealed at a temperature of 400° C. for 30 min and the case when no annealing was performed on the sample, and two cases were compared to each other.

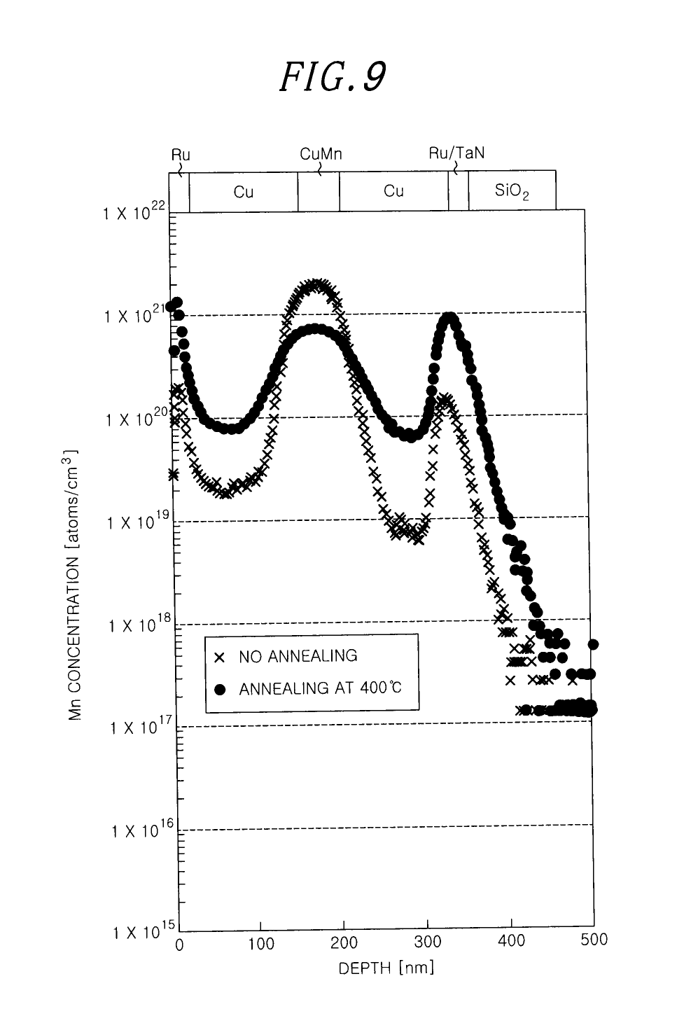

The results are shown in FIG. 9. As shown in FIG. 9, by performing the annealing, Mn was diffused from the CuMn film to the neighboring Cu films and the Mn concentration in the Cu film was increased by about one order of magnitude. In the sample on which no annealing was performed, the reason the Mn concentration near both of the Ru films was increased was that Mn was diffused by heat (about 200° C.) during the formation of the Ru film by the CVD.

From this, it is clear that the alloy component of Mn can be segregated in the interface between the cap layer and the Cu wiring in the above-described three embodiments. Further, since Mn serving as the alloy component is easily bonded with oxygen and Cu, the adhesivity between the cap layer and the Cu—Mn alloy film can be improved.

<Film Forming System Suitable for Implementation of the Embodiments of the Present Invention>

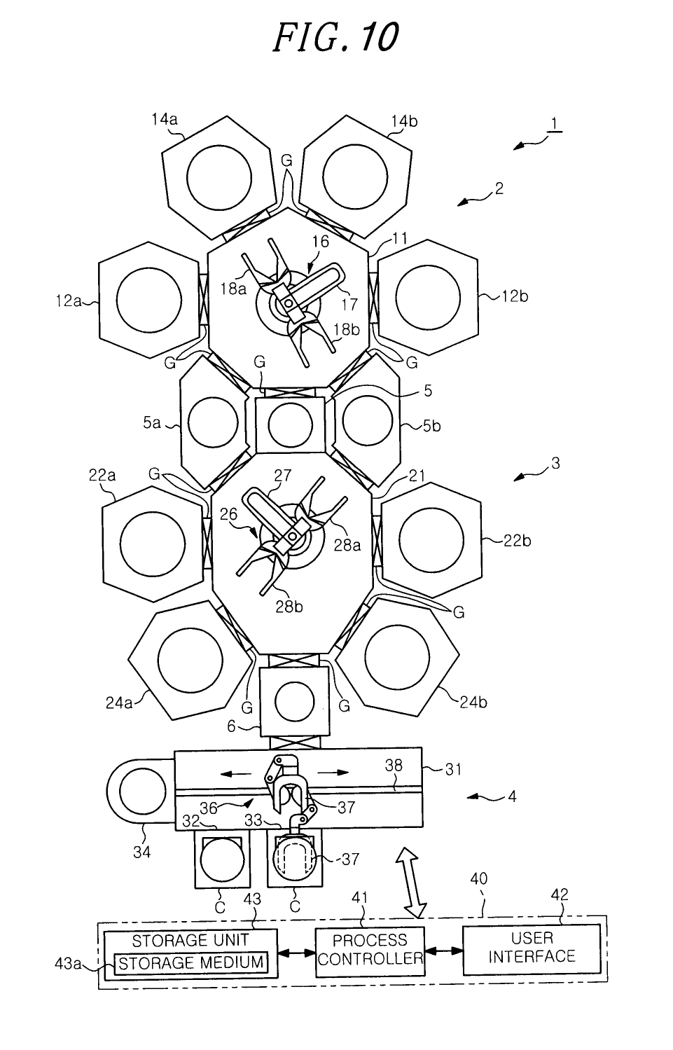

Hereinafter, a film forming system suitable for implementation of the Cu wiring forming method in accordance with the first to the third embodiments of the present invention will be described. FIG. 10 is a top view showing an example of a multi-chamber type film forming system suitable for implementation of the Cu wiring forming methods in accordance with the embodiments of the present invention.

The film forming system 1 includes a first processing unit 2 for forming a barrier film and a Ru liner film, a second processing unit 3 for forming a pure Cu film and a Cu alloy film, and a loading/unloading unit 4. The film forming system 1 is provided for use in a Cu wiring formation on a wafer W, and it is particularly provided to perform processes up to the formation of the Cu alloy film in the first to the third embodiments.

The first processing unit 2 has a first vacuum transfer chamber 11 having a heptagonal cross section, and two barrier film forming apparatuses 12a and 12b and two Ru liner film forming apparatuses 14a and 14b which are connected to walls corresponding to four sides of the first vacuum transfer chamber 11. The barrier film forming apparatus 12a and the Ru liner film forming apparatus 14a are disposed in line symmetry with the barrier film forming apparatus 12b and the Ru liner film forming apparatus 14b.

Degas chambers 5a and 5b each for performing a degas process on the wafer W are connected to walls corresponding to another two sides of the first vacuum transfer chamber 11. Further, an exchange chamber 5 through which the wafer W is transferred between the first vacuum transfer chamber 11 and a second vacuum transfer chamber 21 to be described later is connected to a wall corresponding to the other side of the first vacuum transfer chamber 1 between the degas chambers 5a and 5b of the first vacuum transfer chamber 11.

The barrier film forming apparatuses 12a and 12b, the Ru liner film forming apparatuses 14a and 14b, the degas chambers 5a and 5b, and the exchange chamber 5 are connected to the respective sides of the first vacuum transfer chamber 11 via gate valves G. They communicate with the first vacuum transfer chamber 11 by opening the corresponding gate valves G and are isolated from the first vacuum transfer chamber 11 by closing the corresponding gate valves G.

The inner space of the first vacuum transfer chamber 11 is maintained at a predetermined vacuum atmosphere. Provided in the first vacuum transfer chamber 11 is a first transfer unit 16 for loading and unloading the wafer W into and from the barrier film forming apparatuses 12a and 12b, the Ru liner film forming apparatuses 14a and 14b, the degas chambers 5a and 5b, and the exchange chamber 5. The first transfer unit 16 is disposed substantially at the center of the first vacuum transfer chamber 11, and has a rotatable and extensible/contractible portion 17. The rotatable and extensible/contractible portion 17 has two support arms 18a and 18b for supporting the wafer W at leading ends thereof. The two support arms 18a and 18b are attached to the rotatable and extensible/contractible portion 17 to be directed in the opposite directions.

The second processing unit 3 includes: a second vacuum transfer chamber 21 having an octagonal cross section; two Cu film forming apparatuses 22a and 22b connected to walls corresponding to two opposite sides of the second vacuum transfer chamber 21, each for forming a pure Cu film; and two Cu alloy film forming apparatuses 24a and 24b connected to walls corresponding to another two corresponding sides of the second vacuum transfer chamber 21, each for forming a Cu alloy film.

The degas chambers 5a and 5b are connected to walls corresponding to another two sides of the second vacuum transfer chamber 21, which face the first processing unit 2, and the exchange chamber 5 is connected to a wall corresponding to a side of the second vacuum transfer chamber 21 between the degas chambers 5a and 5b. In other words, the exchange chamber 5 and the degas chambers 5a and 5b are provided between the first vacuum transfer chamber 11 and the second vacuum transfer chamber 21, and the degas chambers 5a and 5b are disposed at both sides of the exchange chamber 5. Moreover, a load-lock chamber 6, which allows the atmospheric transfer and the vacuum transfer, is connected to a wall corresponding to a side of the second vacuum transfer chamber 21, which faces the loading/unloading unit 4.

The Cu film forming apparatuses 22a and 22b, the Cu alloy film forming apparatuses 24a and 24b, the degas chambers 5a and 5b, and the load-lock chamber 6 are connected to the respective sides of the second vacuum transfer chamber 21 via gate valves G. They communicate with the second vacuum transfer chamber 21 by opening the corresponding valves and are isolated from the second vacuum transfer chamber 21 by closing the corresponding gate valves G. The exchange chamber 5 is connected to the second transfer chamber 21 without providing a gate valve therebetween.

The inner space of the second vacuum transfer chamber 21 is maintained at a predetermined vacuum atmosphere. Provided in the second vacuum transfer chamber 21 is a second transfer unit 26 for loading and unloading the wafer W into and from the Cu film forming apparatuses 22a and 22b, the Cu alloy film forming apparatuses 24a and 24b, the degas chambers 5a and 5b, the load-lock chamber 6 and the exchange chamber 5. The second transfer unit 26 is disposed substantially at the center of the second vacuum transfer chamber 21, and has a rotatable and extensible/contractible portion 27. The rotatable and extensible/contractible portion 27 has two support arms 28a and 28b for supporting the wafer W at leading ends thereof. The two support arms 28a and 28b are attached to the rotatable and extensible/contractible portion 27 to be directed in the opposite directions.

The loading/unloading unit 4 has an atmospheric transfer chamber 31 connected to the load-lock chamber 6, and is provided at the opposite side of the second processing unit 3 with the load-lock chamber 6 therebetween. A gate valve G is provided at a wall between the load-lock chamber 6 and the atmospheric transfer chamber 31. Provided at a wall of the atmospheric transfer chamber 31 opposite to the wall connected to the load-lock chamber 6 are two connecting ports 32 and 33 each for connecting carriers C accommodating therein wafers W as target substrates. Each of the connecting ports 32 and 33 is provided with a shutter (not shown). When the carrier C that is either empty or accommodates therein wafers W is directly mounted therein, the shutter is opened and the inner space of the carrier C communicates with that of the atmospheric transfer chamber 31 while preventing intrusion of air from outside.

Further, an alignment chamber 34 is provided at a side of the atmospheric transfer chamber 31, and the alignment of the wafer W is performed therein. Provided in the atmospheric transfer chamber 31 is an atmospheric transfer unit 36 for loading and unloading the wafer W into and from the carrier C and the load-lock chamber 6. The atmospheric transfer unit 36 has two multi-joint arms and can move on a rail 38 along the arrangement direction of the carriers C. Therefore, the atmospheric transfer unit 36 performs the transfer of wafers W, which are mounted on hands 37 provided at leading ends of the respective arms.

The film forming system 1 includes a control unit 40 configured to control the respective components of the film forming system 1. The control unit 40 includes a process controller 41 having a microprocessor (computer) for controlling the respective components of the film forming system 1, a user interface 42 and a storage unit 43. The user interface 42 includes a keyboard through which an operator performs a command input to manage the film forming system 1, a display for visually displaying the operational states of the film forming system 1, and the like. The storage unit 43 stores therein control programs to be used in realizing various processes performed by the film forming system 1 under the control of the process controller 41, programs, i.e., recipes, to be used in operating the respective components of the film forming system 1 to carry out processes under processing conditions and various data. The user interface 42 and the storage unit 43 are connected to the process controller 41.

The recipes are stored in a storage medium 43a inside the storage unit 43. The storage medium 43a may be a hard disk or a portable medium such as a CD-ROM, a DVD, a flash memory or the like. Alternatively, the recipes may be suitably transmitted from other devices via, e.g., a dedicated transmission line.

If necessary, a predetermined recipe is read out from the storage unit 43 under the instruction from the user interface 42 and is executed by the process controller 41. Accordingly, a desired process is performed in the film forming system 1 under the control of the process controller 41.

In the film forming system 1, the wafer W having trenches and/or holes in a predetermined pattern is unloaded from the carrier C and loaded into the load-lock chamber 6 by the atmospheric transfer unit 36. After the pressure in the load-lock chamber 6 is decreased to a vacuum level equivalent to that in the second vacuum transfer chamber 21, the wafer W is unloaded from the load-lock chamber 6 to be loaded into the degas chamber 5a or 5b through the second vacuum transfer chamber 21 by the second transfer unit 26. Thus, the wafer W is subjected to the degas process.

Thereafter, the wafer W is unloaded from the degas chamber 5a or 5b to be loaded into the barrier film forming apparatus 12a or 12b through the first vacuum transfer chamber 11 by the first transfer unit 16. Thus, the barrier film as described above is formed.

After the barrier film is formed, the wafer W is unloaded from the barrier film forming apparatus 12a or 12b to be loaded into the Ru liner film forming apparatus 14a or 14b by the first transfer unit 16. Thus, the Ru liner film as described above is formed.

After the Ru liner film is formed, the wafer W is unloaded from the Ru liner film forming apparatus 14a or 14b and transferred into the exchange chamber 5 by the first transfer unit 16. Thereafter, the wafer W is unloaded from the exchange chamber 5 to be loaded into the Cu film forming apparatus 22a or 22b through the second vacuum transfer chamber 21 by the second transfer unit 26. Thus, the pure Cu film or the pure Cu seed film as described above is formed.

After the pure Cu film or the pure Cu seed film is formed, the wafer W is unloaded from the Cu film forming apparatus 22a or 22b to be loaded into the Cu alloy film forming apparatus 24a or 24b by the second transfer unit 26. Thus, the Cu alloy film as described above is formed therein.

After the Cu alloy film is formed, the wafer W is unloaded from the Cu alloy film forming apparatus 24a or 24b and transferred into the load-lock chamber 6 by the second transfer unit 26. After the pressure in the load-lock chamber is returned to the atmospheric pressure, the wafer W having the Cu film is unloaded by the atmospheric transfer unit 36 and returned to the carrier C. These processes are repeated for the number of wafer W in the carrier.

In accordance with the film forming system 1, the barrier film, the liner film, the Cu film and the Cu alloy film are formed in the vacuum without exposing to the atmosphere. Therefore, oxidation at the interfaces of the films can be avoided, and a high-performance Cu wiring can be obtained.

<Cu Film Forming Apparatus>

Hereinafter, a preferred example of the Cu film forming apparatus 22a (22b) for forming a Cu film will be described.

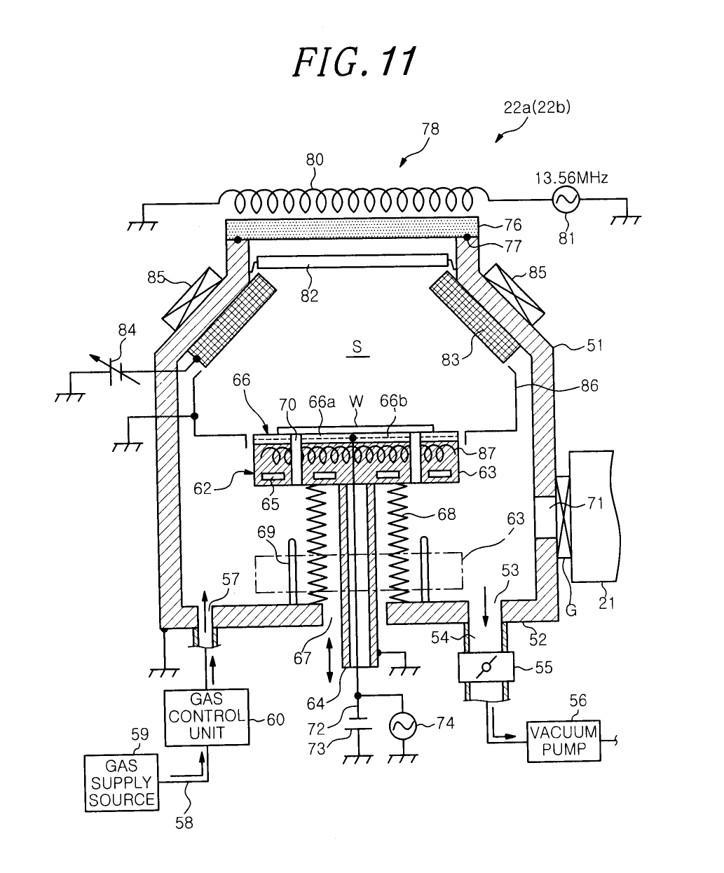

FIG. 11 is a cross sectional view showing an example of the Cu film forming apparatus. Here, an inductively coupled plasma (ICP) type plasma sputtering apparatus that is an iPVD apparatus will be described as an example of the Cu film forming apparatus.

As shown in FIG. 11, the Cu film forming apparatus 22a (22b) includes a cylindrical processing chamber 51 made of, e.g., aluminum or the like. The processing chamber 51 is grounded, and a gas exhaust port 53 is provided at a bottom portion 52 thereof. A gas exhaust line 54 is connected to the gas exhaust port 53. A throttle valve 55 and a vacuum pump 56 for controlling a pressure are connected to the gas exhaust line 54, and thus the inner space of the processing chamber 51 can be evacuated to vacuum. Further, a gas inlet port 57 for introducing a predetermined gas into the processing chamber 51 is provided at the bottom portion 52 of the processing chamber 51. The gas inlet port 57 is connected to a gas supply line 58, and the gas supply line 58 is connected to a gas supply source 59 for supplying a rare gas serving as a plasma excitation gas, e.g., Ar gas, or another required gas, e.g., N₂ gas. The gas supply line 58 is provided with a gas control unit 60 having a gas flow rate controller, a valve or the like.

Provided in the processing chamber 51 is a mounting mechanism 62 for mounting thereon a wafer W as a target substrate. The mounting mechanism 62 has a circular plate-shaped mounting table 63, and a hollow cylindrical column 64, which is grounded, for supporting the mounting table 63. The mounting table 63 is made of a conductive material, e.g., an aluminum alloy or the like, and is grounded via the column 64. The mounting table 63 has therein a cooling jacket 65 through which a coolant is supplied via a coolant path (not shown). Further, in the mounting table 63, a resistance heater 87 coated with an insulating material is provided above the cooling jacket 65. The resistance heater 87 is electrically powered by a power supply (not shown). The mounting table 63 is provided with a thermocouple (not shown), so that the wafer can be controlled to be maintained at a predetermined temperature by controlling a supply of coolant to the cooling jacket 65 and a supply of power to the resistance heater 87 based on the temperature detected by the thermocouple.

Provided on the top surface of the mounting table 63 is a thin circular plate-shaped electrostatic chuck 66 in which an electrode 66b is embedded in a dielectric member 66a made of, e.g., alumina or the like. Accordingly, the wafer W can be electrostatically attracted and held by electrostatic force. The lower portion of the column 64 extends downward through an insertion through hole 67 formed at the center of the bottom portion 52 of the processing chamber 51. The column 64 is vertically movable by an elevation unit (not shown), so that the entire mounting mechanism 62 is vertically moved.

An extensible/contractible metal bellows 68 is provided to surround the column 64. The metal bellows 68 has an upper end hermetically attached to the bottom surface of the mounting table 63 and a lower end hermetically attached to the top surface of the bottom portion 52 of the processing chamber 51. Accordingly, the mounting mechanism can be vertically moved while maintaining the airtightness in the processing chamber 51.

A plurality of, e.g., three (only two are shown in FIG. 11) support pins 69 is uprightly mounted on the bottom portion 52 toward the up side, and pin insertion through holes 70 are formed in the mounting table 63 so as to correspond to the support pins 69. Therefore, when the mounting table 63 is lowered, the upper end portions of the support pins 69 pass through the pin insertion through holes 70 and receive the wafer W, so that the wafer W is transferred to a transfer arm (not shown), which comes from the outside. Therefore, a loading/unloading opening 71 through which the transfer arm moves in and out is provided at a lower sidewall of the processing chamber 51, and an openable/closeable gate valve G is provided at the loading/unloading opening 71. The second vacuum transfer chamber 21 is provided on the opposite side of the gate valve G to the processing chamber 51.

A power supply 73 for the electrostatic chuck 66 is connected to the electrode 66b of the electrostatic chuck 66 through a power supply line 72. By applying a DC voltage from the power supply 73 to the electrode 66b, the wafer W is electrostatically attracted and held by electrostatic force. Further, a high frequency bias power supply 74 is connected to the power supply line 72, so that a high frequency bias power is applied to the electrode 66b of the electrostatic chuck 66 through the power supply line 72 to apply a bias power to the wafer W. The frequency of the high frequency power is preferably in a range from about 400 kHz to 60 MHz, e.g., about 13.56 MHz.

A high frequency transmission plate 76 made of a dielectric material, e.g., alumina or the like, is hermetically provided at the ceiling portion of the processing chamber 51 via a seal member 77 such as an O-ring or the like. Further, a plasma generating source 78, for generating a plasma from a rare gas as a plasma excitation gas, e.g., Ar gas, in a processing space S of the processing chamber 51, is provided above the transmission plate 76. The plasma excitation gas may be another rare gas, e.g., He, Ne, Kr or the like, other than Ar.

The plasma generating source 78 has an induction coil 80 disposed so as to correspond to the transmission plate 76. A high frequency power supply 81 having a high frequency of, e.g., 13.56, MHz for plasma generation is connected to the induction coil 80, so that a high frequency power is introduced into the processing space S through the transmission plate 76 and an induced electric field is formed.

Moreover, a baffle plate 82 made of e.g. aluminum, is provided directly under the transmission plate 76 to diffuse the introduced high frequency power. Further, disposed below the baffle plate 82 to surround the upper region of the processing space S is a target 83 formed of Cu having an annular shape with an inwardly upwardly inclined cross section (truncated cone shape), for example. A variable-voltage DC power supply 84 is connected to the target 83 in order to apply a DC power for attracting Ar ions. Alternatively, an AC power supply may be used instead of the DC power supply.

Further, a magnet 85 is provided at the outer circumferential side of the target 83 to apply a magnetic field to the target 83. The target 83 is sputtered by Ar ions in the plasma so that Cu atoms or Cu atomic groups are emitted from the target 83 and they are mostly ionized while passing through the plasma.

Moreover, a cylindrical protection cover member 86 made of, e.g., aluminum or copper, is provided under the target 83 to surround the processing space S. The protection cover member 86 is grounded and a lower portion thereof is bent inward so as to be positioned near the side portion of the mounting table 63. Thus, an inner end of the protection cover member 86 is disposed to surround the outer peripheral side of the mounting table 63.

Further, the respective sections of the Cu film forming apparatus are controlled by the above-described control unit 40.

In the Cu film forming apparatus configured as described above, the wafer W is loaded into the processing chamber 51 shown in FIG. 11 and mounted on the mounting table 63. Then, the wafer W is electrostatically attracted to and held on the electrostatic chuck 66, and the following processes are carried out under the control of the control unit 40. At this time, the temperature of the mounting table 63 is controlled by controlling the supply of coolant to the cooling jacket or the supply of power to the resistance heater 87 based on the temperature detected by the thermocouple (not shown).

First, the processing chamber 51 is set to be maintained at a predetermined vacuum state by operating the vacuum pump 56. Then, Ar gas is supplied to the processing chamber 51 at a predetermined flow rate by controlling the gas control unit 60, and at the same time, the processing chamber 51 is maintained at a predetermined vacuum level by controlling the throttle valve 55. Next, a DC power is applied to the Cu target 83 from the variable DC power supply 84, and a high frequency power (plasma power) is supplied to the induction coil 80 from the high frequency power supply 81. Further, a predetermined high frequency bias power is supplied to the electrode 66b of the electrostatic chuck 66 from the high frequency bias power supply 74.

Accordingly, in the processing chamber 51, an Ar plasma is generated by the high frequency power supplied to the induction coil 80 and thus Ar ions are generated. These ions are attracted toward the target 83 by the DC voltage applied to the target 83 and collide with the target 83. Hence, the target 83 is sputtered to emit Cu particles. At this time, the amount of Cu particles emitted from the target 83 is optimally controlled by the DC voltage applied to the target 83.

The Cu atom groups and the Cu atoms which are Cu particles emitted from the sputtering target 83 are mostly ionized while passing through the plasma. Here, the Cu particles are scattered downward in a state where ionized Cu ions and electrically neutral Cu atoms are mixed. Particularly, when the pressure in the processing chamber 51 is increased to a certain level, a plasma density is increased so that the Cu particles can be ionized with high efficiency. The ionization rate at this time is controlled by the high frequency power supplied from the high frequency power supply 81.

When the Cu ions are introduced into an ion sheath region formed on the wafer W with a thickness of about a few mm by the high frequency bias power applied to the electrode 66b of the electrostatic chuck 66 from the high frequency bias power supply 74, the Cu ions are rapidly attracted with strong directivity toward the wafer W and deposited on the wafer W. As a consequence, the Cu thin film is formed.

At this time, the wafer temperature is set to be maintained at a high level in a range from about 65° C. to 350° C., and the bias power applied from the high frequency bias power supply 74 to the electrode 66b of the electrostatic chuck 66 is controlled. With such control, the film formation using Cu and the etching using Ar are controlled to improve the mobility of Cu. As a result, the pure Cu can be filled with good fillability even in a trench or a hole having a small opening. Specifically, on the assumption that the Cu film forming amount (film forming rate) is T_{D} and the etching amount (etching rate) by ions of the plasma generation gas is T_{E}, it is preferable to control the bias power such that 0≦T_{E}/T_{D}<1 and further 0<T_{E}/T_{D}<1 is satisfied.

In view of ensuring good fillability, the pressure in the processing chamber 51 (processing pressure) is preferably set in a range from about 1 mTorr to 100 mTorr (from about 0.133 Pa to 13.3 Pa) and more preferably set in a range from about 35 mTorr to 90 mTorr (from about 4.66 Pa to 12.0 Pa). Further, the DC power supplied to the Cu target is preferably set in a range from about 4 kW to 12 kW and more preferably in a range from about 6 kW to 10 kW.

Further, when the opening of the trench or the hole is large, the film formation can be carried out by setting the wafer temperature to a low level in a range from −50° C. to 0° C. and further decreasing the pressure in the processing chamber 51. Accordingly, the film forming rate can be increased. In this case, the film forming method is not limited to the iPVD, and the conventional PVD such as the conventional sputtering, the ion plating or the like can be employed.

<Cu Alloy Film Forming Apparatus>

The Cu alloy film forming apparatus 24a (24b) uses a plasma sputtering apparatus having the same configuration as that of the Cu film forming apparatus 22a (22b) shown in FIG. 11 except that the target of the Cu film forming apparatus 22a or 22b shown in FIG. 11 is not pure Cu but Cu alloy. When the fillability is not a considerable matter, the conventional PVD such as the conventional sputtering, the ion plating or the like may be used without being limited to the iPVD.

<Barrier Film Forming Apparatus>

The barrier film forming apparatus 12a (12b) uses a film forming apparatus having the same configuration as that of the film forming apparatus shown in FIG. 11 except using a different material of the target 83, to form a film by the plasma sputtering. The film formation method is not limited to the plasma sputtering and may be other PVD such as the conventional sputtering, the ion plating or the like, the chemical vapor deposition (CVD) or the atomic layer deposition (ALD), or the plasma CVD or the plasma ALD. In view of reduction of impurities, the PVD is preferred.

<Ru Film Forming Apparatus>

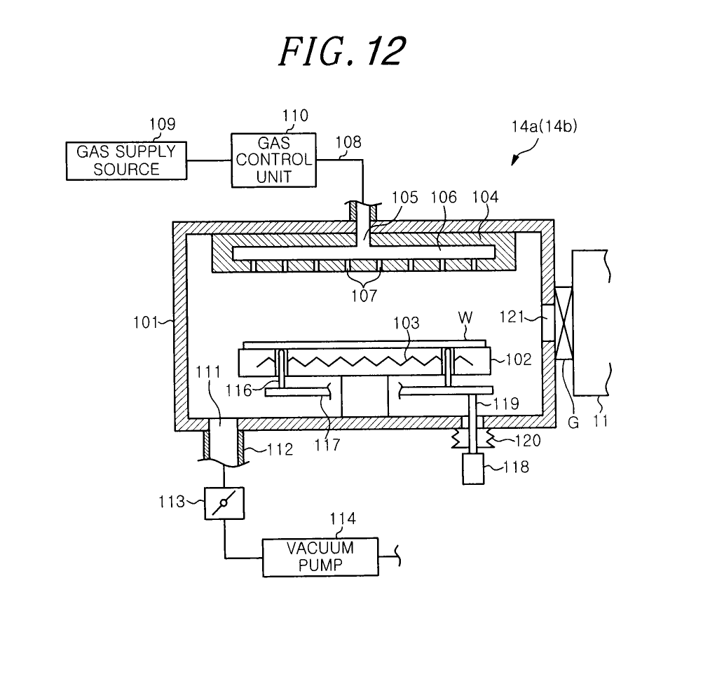

Hereinafter, a Ru film forming apparatus 14a (14b) for forming a Ru liner film will be described. The Ru liner film may be preferably formed by a thermal CVD. FIG. 12 is a cross sectional view showing an example of the Ru film forming apparatus for forming a Ru film by the thermal CVD.

As shown in FIG. 12, the Ru film forming apparatus 14a (14b) includes a cylindrical processing chamber 101 made of, e.g., aluminum or the like. The processing chamber 101 has therein a mounting table 102 made of ceramic, e.g., AlN, for mounting thereon the wafer W, and the mounting table 102 has therein a heater 103. The heater 103 generates a heat by a power supplied from a heater supply (not shown).

A shower head 104 is provided on the ceiling wall of the processing chamber 101 so as to face the mounting table 102. Through the shower head 104, a purge gas or a processing gas for forming a Ru film is introduced into the processing chamber 101 in the form of shower. The shower head 104 has a gas inlet port 105 at an upper portion thereof and a gas diffusion space 106 therein. A plurality of gas injection openings 107 is formed in the bottom of the shower head 104. A gas supply line 108 is connected to the gas inlet port 105, and a gas supply source 109 is connected to the gas supply line 108 in order to supply the purge gas or the processing gas for forming the Ru film. Further, a gas control unit 110 including a gas flow rate controller, a valve or the like is disposed on the gas supply line 108. As described above, ruthenium carbonyl (Ru₃(CO)₁₂) may be preferably used as a Ru forming gas. The Ru film can be formed by thermally decomposing ruthenium carbonyl.

A gas exhaust port 111 is provided in the bottom portion of the processing chamber 101, and a gas exhaust line 112 is connected to the gas exhaust port 111. A throttle valve 113 and a vacuum pump 114 which control the pressure are connected to the gas exhaust line 112, so that the processing chamber 101 can be exhausted to vacuum.

Three wafer support pins 116 (only two pins are shown) for transferring a wafer are provided in the mounting table 102 such that they can protrude from and retreat into the surface of the mounting table 102. The wafer support pins 116 are fixed to a support plate 117. The wafer support pins 116 are vertically moved together with the support plate 117 by vertically moving a rod 119 by a driving unit 118 such as an air cylinder or the like. Reference numeral 120 denotes a bellows. A wafer loading/unloading opening 121 is formed at a sidewall of the processing chamber 101, so that a wafer W can be loaded from and unloaded into the first vacuum transfer chamber 11 in a state where a gate valve G is open.

In the Ru film forming apparatus 14a (14b), the gate valve G is open and the wafer W is mounted on the mounting table 102. Then, the gate valve G is closed, and the processing chamber 101 is evacuated by the vacuum pump 114 to control the pressure in the processing chamber 101 to be maintained at a predetermined level. In a state where the wafer W is heated to a predetermined temperature through the mounting table 102 by the heater 103, a processing gas such as ruthenium carbonyl (Ru₃(CO)₁₂) or the like is introduced into the processing chamber 101 from the gas supply source 109 through the gas supply line 108 and the shower head 104. Accordingly, the reaction of the processing gas is performed on the surface of the wafer W, and the Ru film is formed on the wafer W.

The Ru film may be formed by using another film forming material other than ruthenium carbonyl, e.g., the aforementioned pentadienyl ruthenium compounds, together with decomposition gas such as O₂ gas. In addition, the Ru film may be formed by the PVD. However, a CVD using ruthenium carbonyl may be preferred for the purpose of obtaining good step coverage and reducing impurities in the film.

<Apparatus Used for Other Processes>

Although the processes up to the formation of the Cu alloy film in the first to the third embodiments can be performed by the above-described film forming system 1, the post processes such as the annealing process, the CMP process, the cap layer forming process and the like may be performed on the wafer W unloaded from the film forming system 1 by using an annealing apparatus, a CMP apparatus, and a cap layer forming apparatus. These apparatuses have general configurations. These apparatuses and the film forming system 1 constitute the Cu wiring forming system, and integrally controlled by a common control unit having the same function as that of the control unit 40. Accordingly, the methods described in the first to the third embodiments can be integrally controlled by a single recipe.

<Effects of the First to the Third Embodiments>

In accordance with the first to the third embodiments, the pure Cu film is formed by the PVD, so that pure Cu exists on the surface in the recess such as a trench or a hole, and the Cu alloy film is formed by the PVD beyond the upper end of the recess. Before the cap layer is formed and/or when the cap layer is formed, the alloy component contained in the Cu alloy film are segregated in a region including a portion corresponding to the interface between the Cu wiring and the cap layer. Therefore, when the cap layer is formed, a sufficient amount of the alloy component exits in the interface between the cap layer and the Cu wiring, and the adhesivity between the cap layer and the Cu wiring can be improved.

Further, since the alloy component is segregated in the interface between the cap layer and the Cu wiring, the concentration of the alloy component in the Cu wiring is low, which makes it possible to form a Cu wiring having a lower resistance than that of a Cu wiring formed of a Cu alloy.

<Other Application>

While the embodiments of the present invention have been described, the present invention may be variously modified without being limited to the above embodiments. For example, the film forming system is not limited to the type shown in FIG. 10, and may be of a type in which all the film forming apparatuses are connected to a single transfer unit. Further, instead of the multi-chamber type system shown in FIG. 10, a system may be employed in which some of a barrier film, a Ru liner film, a pure Cu film (pure Cu seed film), and a Cu alloy film are formed in the same film forming system and the other films are formed in separate apparatuses through the exposure to the atmosphere. Alternatively, the respective films may be formed in separate apparatuses through the exposure to the atmosphere.

The above embodiments have described the example in which the method of the present invention is applied to a wafer having a trench and a via (hole) as a recess. However, the present invention may be applied to the case in which the wafer has only a trench as a recess or the case in which the wafer has only a hole as a recess. Moreover, the present invention may be applied to filling in devices having various structures such as a single damascene structure, a double damascene structure, a 3D mounting structure or the like. Further, although a semiconductor wafer has been described as an example of a substrate to be processed in the above embodiments, the semiconductor wafer includes a compound semiconductor such as GaAs, SiC, GaN or the like as well as a silicon substrate, and the present invention may be applied to a glass substrate for use in FPD (flat panel display) such as a liquid display device or the like, a ceramic substrate or the like without being limited to a semiconductor wafer.

What is claimed is:

1. A Cu wiring forming method for forming a Cu wiring by filling Cu in a recess, which is formed in a substrate in a predetermined pattern, the Cu wiring forming method comprising:
forming a barrier film at least on a surface of the recess;
forming a pure Cu film by a physical vapor deposition (PVD) so that pure Cu exists at least on a surface in the recess;
forming a Cu alloy film formed of a Cu alloy beyond an upper end of the recess by the PVD;
forming a Cu wiring in the recess by polishing the entire surface of the substrate by a chemical mechanical polishing;
forming a cap layer made of a dielectric material on the Cu wiring; and
forming a segregation layer of an alloy component contained in the Cu alloy film by segregating the alloy component in a region including a portion corresponding to an interface between the Cu wiring and the cap layer by diffusing the alloy component in the Cu alloy film before said forming the cap layer and/or during said forming the cap layer,
wherein the segregation layer of the alloy component is formed in the interface between the Cu wiring and the cap layer.

2. The Cu wiring forming method of claim 1, further comprising forming a Ru film between said forming the barrier film and said forming the pure Cu film.

3. The Cu wiring forming method of claim 2, wherein the Ru film is formed by a chemical vapor deposition.

4. The Cu wiring forming method of claim 1, wherein, in said forming the pure Cu film, the pure Cu is filled entirely in the recess.

5. The Cu wiring forming method of claim 1, wherein, in said forming the pure Cu film, a pure Cu seed film is formed as the pure Cu film on the surface in the recess.

6. The Cu wiring forming method of claim 1, wherein, in said forming the pure Cu film, the pure Cu is filled such that an upper space in the recess remains empty.

7. The Cu wiring forming method of claim 1, wherein said forming the segregation layer of the alloy component includes annealing the substrate after said forming the Cu alloy film.

8. The Cu wiring forming method of claim 1, wherein said forming the segregation layer of the alloy component includes heating the substrate during said forming the Cu alloy film.

9. The Cu wiring forming method of claim 1, wherein said forming the segregation layer of the alloy component includes heating the substrate during said forming the cap layer.

10. The Cu wiring forming method of claim 1, wherein said forming the pure Cu film is carried out by an apparatus for generating a plasma with a plasma generation gas in a processing chamber where the substrate is accommodated, ionizing Cu scattered from a target formed of the pure Cu in the plasma, and attracting Cu ions onto the substrate by applying a bias power to the substrate.

11. The Cu wiring forming method of claim 1, wherein said forming the Cu alloy film is carried out by an apparatus for generating a plasma with a plasma generation gas in a processing chamber where the substrate is accommodated, ionizing Cu and the alloy component scattered from a target formed of the Cu alloy in the plasma, and attracting Cu ions and ions of the alloy component onto the substrate by applying a bias power to the substrate.

12. The Cu wiring forming method of claim 1, wherein the Cu alloy forming the Cu alloy film is selected from a group consisting of Cu—Al, Cu—Mn, Cu—Mg, Cu—Ag, Cu—Sn, Cu—Pb, Cu—Zn, Cu—Pt, Cu—Au, CuNi, Cu—Co, and Cu—Ti.

13. The Cu wiring forming method of claim 12, wherein the Cu alloy forming the Cu alloy film is Cu—Mn.

14. The Cu wiring forming method of claim 12, wherein the Cu alloy forming the Cu alloy film is Cu—Al.

15. The Cu wiring forming method of claim 1, wherein the barrier film is selected from a group consisting of a Ti film, a TiN film, a Ta film, a TaN film, a Ta/TaN bilayered film, a TaCN film, a W film, a WN film, a WCN film, a Zr film, a ZrN film, a V film, a VN film, a Nb film and a NbN film.

16. The Cu wiring forming method of claim 1, wherein the barrier film is formed by the PVD.

17. A storage medium storing a program executed on a computer to control a Cu wiring forming system, wherein the program, when executed on the computer, controls the Cu wiring forming system to perform the Cu wiring forming method, which includes:
forming a barrier film at least on a surface of the recess;
forming a pure Cu film by a physical vapor deposition (PVD) so that pure Cu exists at least on a surface in the recess;
forming a Cu alloy film formed of a Cu alloy beyond an upper end of the recess by the PVD;
forming a Cu wiring in the recess by polishing the entire surface of the substrate by a chemical mechanical polishing;
forming a cap layer made of a dielectric material on the Cu wiring; and
forming a segregation layer of an alloy component contained in the Cu alloy film by segregating the alloy component in a region including a portion corresponding to an interface between the Cu wiring and the cap layer by diffusing the alloy component in the Cu alloy film before said forming the cap layer and/or during said forming the cap layer,
wherein the segregation layer of the alloy component is formed in the interface between the Cu wiring and the cap layer.
